(19) United States
(12) Patent Application Publication
(10) Pub. No.: US 2014/0225789 A1
(43) Pub. Date: Aug. 14, 2014

(54) STRUCTURE

(71) Applicant: Tomofumi Katayama, Osaka-shi (JP)

(72) Inventor: Tomofumi Katayama, Osaka-shi (JP)

(73) Assignee: SHARP KABUSHIKI KAISHA, Osaka-shi, Osaka (JP)

(21) Appl. No.: 14/347,087

(22) PCT Filed: Aug. 9, 2012
(86) PCT No.: PCT/JP2012/070389

§ 371 Date: Mar. 25, 2014

(30) Foreign Application Priority Data
Oct. 28, 2011 (JP) 2011-237999

(51) Int. Cl. H05K 5/06; H01Q 1/24

(52) U.S. Cl. CPC H05K 5/061; H01Q 1/243
USPC 343/702; 361/679.01

(57) ABSTRACT

A structure includes: a casing being made of a dielectric material; an electrically conductive pattern provided on a surface of the casing; an electrically conductive member including: a penetrating part; a first part; and a second part, wherein the first part and the second part catch the electrically conductive pattern and a surface; and a squeeze gasket being composed of an elastic body.

### TECHNICAL FIELD

The present invention relates to a structure including a casing and an electrically conductive pattern.

### BACKGROUND ART

In recent years, there has been developed an electronic device including a casing having an electrically conductive pattern provided on its surface.

For example, Patent Literature 1 describes a method for manufacturing a printed antenna, including: a fist step of forming a through hole in a non-conductive object committed to print; a second step of placing a contact member having electrical conductivity in the through hole; a third step of printing, on one surface of the object committed to print, an antenna pattern with use of an electrically conductive ink or a metal powder-containing ink so that the antenna pattern overlaps a part of one end face of the contact member; and a fourth step of subjecting the surface of the antenna pattern having been formed in the third step to plating, wherein a part of plating having been formed in the fourth step is electrically connected to the contact member.

### CITATION LIST

### Patent Literature

Patent Literature 1
Japanese Patent Application Publication, Tokukai, No. 2010-166379 A (Publication Date: Jul. 29, 2010)

### SUMMARY OF INVENTION

### Technical Problem

However, the technique described in Patent Literature 1 has the problem that there may be cases where waterproof and dustproof properties cannot be ensured due to a minute gap occurring between the through hole and the contact member inserted into the through hole.

The present invention has been attained in view of the above problem, and a main object of the present invention is to provide a technique for improving waterproof and dustproof properties of a casing having an electrically conductive pattern formed on its surface.

### Solution to Problem

A structure according to the present invention includes: a casing being made of a dielectric material; an electrically conductive pattern being provided on a first surface of the casing; an electrically conductive member including: a penetrating part penetrating the casing so as to extend from the first surface to a second surface opposite the first surface; a first part extending from the penetrating part toward the first surface; and a second part extending from the penetrating part toward the second surface, wherein the first part and the second part catch the electrically conductive pattern and the second surface therebetween; and a squeeze gasket being composed of an elastic body and placed between the casing and the electrically conductive member.

According to the above arrangement, the electrically conductive member penetrates the casing and holds the casing and the electrically conductive pattern from both sides thereof between the first part and the second part thereof. This causes the electrically conductive member to be fastened to the casing. Further, the first part comes into contact with the electrically conductive pattern. This enables electrical connection between the electrically conductive member and the electrically conductive pattern, thus allowing power supplied from the second surface side of the casing to be fed to the electrically conductive pattern.

In the above arrangement, the squeeze gasket composed of an elastic body is placed between the electrically conductive member and the casing. This makes it possible to seal a gap between the electrically conductive member and the casing, thus achieving improvements in waterproof and dustproof properties of the structure.

### Advantageous Effects of Invention

A structure according to the present invention enables sealing a gap between the electrically conductive member and the casing. This makes it possible to achieve improvements in waterproof and dustproof properties of the structure.

### BRIEF DESCRIPTION OF DRAWINGS

FIG. 1

(a) of FIG. 1 is a side cross-sectional view schematically showing the configuration of a structure according to one embodiment (First Embodiment) of the present invention. (b) of FIG. 1 is a side cross-sectional view schematically showing the configuration of an electrically conductive member according to one embodiment (First Embodiment) of the present invention.

FIG. 2 is an oblique view showing an example of an electronic device according to one embodiment (First Embodiment) of the present invention.

FIG. 3 is a side cross-sectional view showing a direction in which a force is applied in a structure according to one embodiment (First Embodiment) of the present invention.

FIG. 4 is a side cross-sectional view showing a modified electrically conductive member according to one embodiment (First Embodiment) of the present invention.

FIG. 5 is a side cross-sectional view showing a modified structure according to one embodiment (First Embodiment) of the present invention.

FIG. 6 is a side cross-sectional view schematically showing the configuration of a structure according to one embodiment (Second Embodiment) of the present invention.

FIG. 7 is a side cross-sectional view showing a modified electrically conductive member according to one embodiment (Second Embodiment) of the present invention.

FIG. 8 is a side cross-sectional view showing a modified structure according to one embodiment (Second Embodiment) of the present invention.

FIG. 9 is a side cross-sectional view schematically showing the configuration of a structure according to one embodiment (Third Embodiment) of the present invention.

FIG. 10 is a side cross-sectional view showing a direction in which a force is applied in a structure according to one embodiment (Third Embodiment) of the present invention.

FIG. 11 is a side cross-sectional view showing a modified electrically conductive member according to one embodiment (Third Embodiment) of the present invention.

### DESCRIPTION OF EMBODIMENTS

### First Embodiment

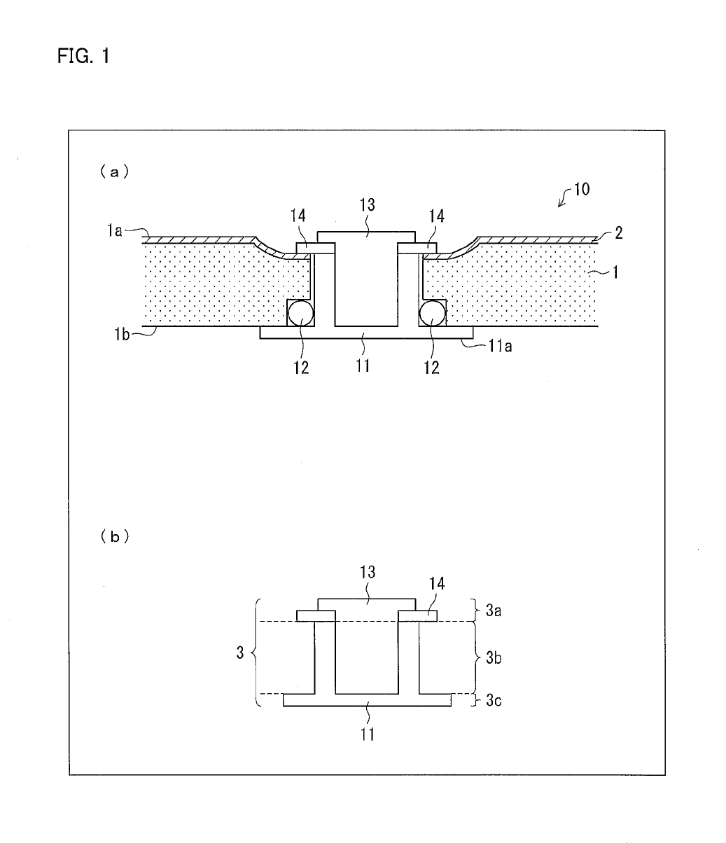

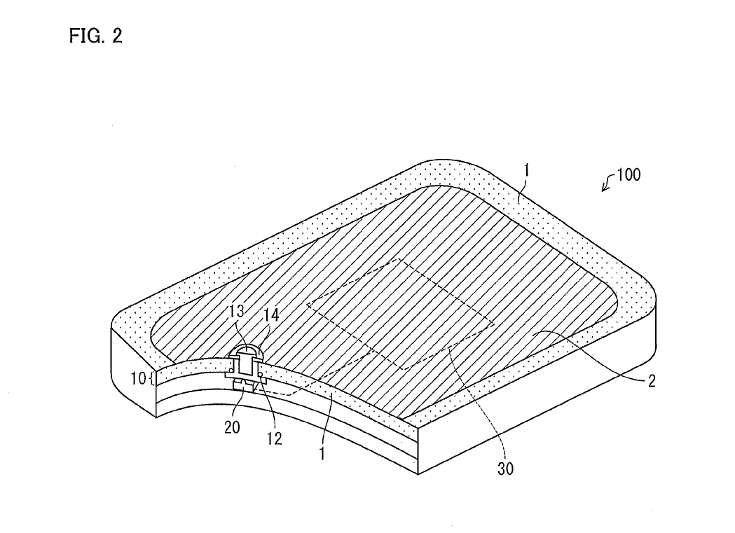

(a) of FIG. 1 is a side cross-sectional view schematically showing the configuration of a structure 10 according to the present embodiment. (b) of FIG. 1 is a side cross-sectional view schematically showing the configuration of an electrically conductive member 15 according to the present embodiment. FIG. 2 is an oblique view schematically showing the configuration of a wireless device 100 according to the present embodiment. Note that in FIG. 2, the wireless device 100 is partially cut away to show a cross section of the wireless device 100, for ease of explanation.

As shown in FIG. 2, the First Embodiment discusses a configuration in which a structure according to the present invention is incorporated into a wireless device. The present invention is, however, not limited to this configuration. That is, a structure according to the present invention includes an electrically conductive pattern available for an antenna element, a signal transmission path, a power transmission path, or the like, and can be suitably incorporated into various electronic devices which require an antenna element, a signal transmission path, or a power transmission path.

The structure 10 includes a casing 1, an electrically conductive pattern 2, an electrically conductive member 3 (electrically conductive pin 11, a screw 13, and a metal plate nut 14), and a squeeze gasket 12. Further, the wireless device 100 includes the structure 10, a connecting section 20, and a wireless circuit 30.

(Casing)

The casing 1 is made of a dielectric material and constitutes a casing of an electronic device (in the present embodiment, the wireless device 100) including the structure 10. In the present embodiment, the casing 1 is shaped like a plate. However, this is not the only possibility. The casing 1 may be of any shape conforming to an electronic device which includes the structure 10. In (a) of FIG. 1, a surface 1a of the casing 1 on an upper side of a sheet on which FIG. 1 is illustrated corresponds to an outer side of the casing 1, while a surface 1b of the casing 1 on s lower side of the sheet on which FIG. 1 is illustrated corresponds to an inner side of the casing 1 (see FIG. 2).

Further, as shown in (a) of FIG. 1, the casing 1 may be recessed in the form of a bowl in a portion thereof where the metal plate nut 14 and others are placed. With this arrangement, it is possible to prevent a tip of the screw 13 or the like from protruding through the outer side of the casing 1 and to flatten an outer surface of the casing 1.

(Electrically Conductive Pattern)

The electrically conductive pattern 2 is an electrical conductor provided on the surface 1a of the casing 1. The electrically conductive pattern may be, for example, an electrically conductive film formed by coating a surface of the casing 1 with electrically conductive paste or an electrically conductive film having flexibility, such as a flexible printed board or a seal having electrical conductivity. Alternatively, the electrically conductive pattern may be composed of a metal plate, plating, or the like. Although the present embodiment deals with the electrically conductive pattern 2 used as an antenna element, the present invention is not limited to this. Alternatively, the electrically conductive pattern 2 may be used for electrical connection between components which are placed in an area where the electrically conductive pattern 2 is provided in an electronic device.

In a case where the electrically conductive pattern 2 is constituted by an electrically conductive film formed by coating the surface of the casing 1 with electrically conductive paste, the electrically conductive paste is an electrical conductor material having viscosity and is composed of at least metal powder and a solvent. The electrically conductive paste preferably employed can be an electrically conductive paste composed of metal powder, a binder resin, and a solvent. For example, the electrically conductive film formed by coating with the electrically conductive paste may have the solvent removed therefrom due to drying or may have the solvent partly remained therein. The coating with the electrically conductive paste can be achieved in a variety of methods. However, coating of the electrically conductive paste is preferably applied by printing using a printing plate having flexibility (e.g., flexographic printing, offset printing, silk printing, pad printing, or the like), so as to conform to the shape of the casing 1.

Formation of the electrically conductive pattern 2 by coating with the electrically conductive paste enables not only reduction of a thickness of an electrically conductive pattern, but also the ease with which the electrically conductive pattern is formed into a curved shape. This makes it possible to offer additional degrees of freedom in the design of the electrically conductive pattern 2.

Further, coating with the electrically conductive paste by printing using a printing plate having flexibility (flexographic printing, offset printing, silk printing, pad printing, or the like) enables not only successful printing of the electrically conductive pattern in conformity of the shape of the casing and the like, but also contribution to mass production and the like of the structure.

Note that even in a case where the electrically conductive pattern 2 is constituted by an electrically conductive film having flexibility, such as a flexible printed board or a sticker having electrical conductivity, it is possible to immobilize the electrically conductive pattern 2 in any shape. This makes it possible to offer additional degrees of freedom in the design of the electrically conductive pattern 2.

That is, in a case where the electrically conductive pattern 2 is constituted by an electrically conductive film not having shape retention property (not having self-shape retention property) by itself, including an electrically conductive film having flexibility, such as a flexible printed board, and an electrically conductive film formed by coating with an electrically conductive paste, it is possible to offer additional degrees of freedom in the design of the electrically conductive pattern 2.

Alternatively, the electrically conductive pattern 2 may be composed of a metal plate formed in a desired shape or may be composed of plating.

(Electrically Conductive Member)

As shown in (b) of FIG. 1, the electrically conductive member 3 is composed of a first part 3a, a penetrating part 3b, and a second part 3c. The penetrating part 3b is a penetrating part 3b penetrating the casing 1 so as to extend from the surface 1a to the surface 1b. The first part 3a is a part extending from the penetrating part 3b toward the surface 1a. The second part 3c is a part extending from the penetrating part 3b toward the surface 1b. The electrically conductive member 3 is arranged such that the first part 3a and the second part 3c catch the electrically conductive pattern 2 and the surface 1b therebetween. With this arrangement, the electrically conductive member 3 is fastened to the casing 1, and the first part 1a comes into contact with the electrically conductive pattern 2. This enables electrical connection between the electrically conductive member 3 and the electrically conductive pattern 2, thus allowing power conveyed from the surface 1b side of the casing 1 to be fed to the electrically conductive pattern 2.

In the present embodiment, the electrically conductive member 3 is constituted by the electrically conductive pin 11, the screw 13, and the metal plate nut 14. That is, the first part 3a is constituted by one part of the screw 13 and the metal plate nut 14. The penetrating part 3b is constituted by one part of the electrically conductive pin 11 and the other part of the screw 13. The second part 3c is constituted by the other part of the electrically conductive pin 11.

The electrically conductive member 3 needs only to be arranged such that there is conductive connection between the surface of the inner side of the second part 3c (i.e., the surface 11a of the electrically conductive pin 11) and a part (i.e., the metal plate nut 14) of the first part 3a which part comes into contact with the electrically conductive pattern 2. Thus, the electrically conductive member 3 is not necessarily composed entirely of an electrical conductor. In the present embodiment, the electrically conductive pin 11 and the metal plate nut 14 need only to be electrical conductors. Note that the electrical conductor herein encompasses an insulator (e.g., resin) which is plated with an electrical conductor such as metal, as well.

The electrically conductive pin 11 has a screw hole formed therein at a position where the screw 13 is to be inserted. This fastens the screw 13 and the electrically conductive pin 11, thereby catching the casing 1 and the electrically conductive pattern 2.

Further, the surface 11a serves as a power-feed contact point for feeding, to the electrically conductive pattern 2, power supplied from the inner side of the casing 1. Power feed to the surface 11a may be carried out with use of, for example, a spring or the like.

(Squeeze Gasket)

The squeeze gasket 12 refers to a molded gasket that is used to provide a squeeze, such as an O-ring, a square ring, or the like. The squeeze gasket 12 can be formed of an elastic body such as rubber or silicon.

Such a squeeze gasket 12 is placed between the electrically conductive member 3 and the casing 1. This makes it possible to seal a gap between the electrically conductive member 3 and the casing 1, thus achieving improvements in waterproof and dustproof properties of the structure 10.

Further, in the present embodiment, the squeeze gasket 12 is placed on the inner side of the casing 1 (i.e., on the lower side of the sheet on which FIG. 1 is illustrated). In other words, the squeeze gasket 12 is placed between the casing 1 and the second part 3c.

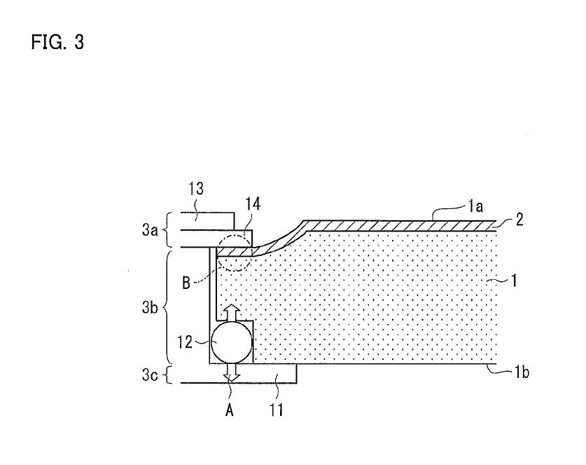

In this case, as shown in FIG. 3, the squeeze gasket 12 applies, by its elastic force, a force A directing from the surface 1a to the surface 1b, to the second part 3c (the electrically conductive pin 11) of the electrically conductive member 3. This force is transmitted to the metal plate nut 14 which is fastened to the electrically conductive pin 11. As such, a pressing force of the metal plate nut 14 toward the electrically conductive pattern 2 increases at a joint part B between the metal plate nut 14 and the electrically conductive pattern 2. This makes it possible to enhance the conductive connection between the electrically conductive member 3 (the metal plate nut 14) and the electrically conductive pattern 2.

(Modified Electrically Conductive Member)

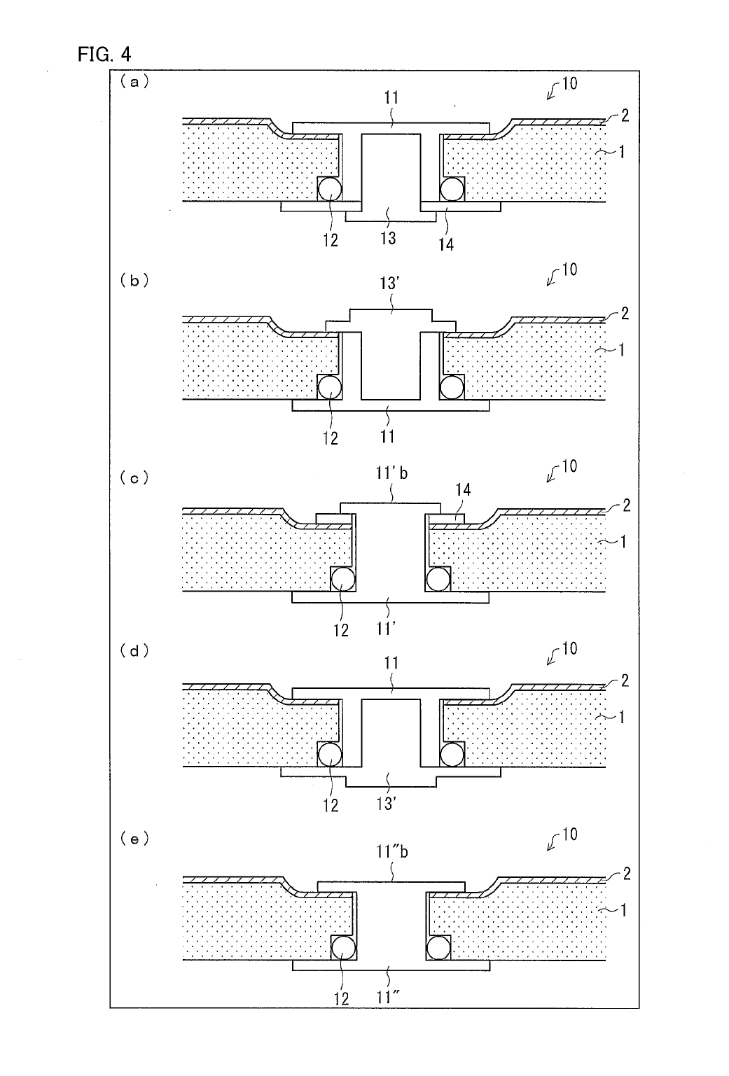

FIG. 4 is a view showing variations of the electrically conductive member 3. As shown in (a) of FIG. 4, the placements of the electrically conductive pin 11 and the screw 13 may be reversed. In this case, the power-feed contact point for feeding, to the electrically conductive pattern 2, power supplied from the inner side of the casing 1 may be the metal plate nut 14 or the screw 13.

Alternatively, as shown in (b) of FIG. 4, a member 13′, into which the metal plate nut 14 and the screw 13 are integrally formed, may be employed.

Further alternatively, as shown in (c) of FIG. 4, an electrically conductive pin 11′ fixed to the casing 1 by caulking a surface 11′b of the electrically conductive pin 11′ on the outer side of the casing 1, instead of being provided with the screw 13 may be employed.

Alternatively, as shown in (d) of FIG. 4, a member 13′, into which the metal plate nut 14 and the screw 13 both provided in the configuration of (a) of FIG. 4 are integrally formed, may be employed. As shown in (e) of FIG. 4, an electrically conductive pin 11″, into which the metal plate nut 14 and the electrically conductive pin 11′ both provided in the configuration of (c) of FIG. 4 are integrally formed, may be employed.

(Modification of the Placement of the Squeeze Gasket)

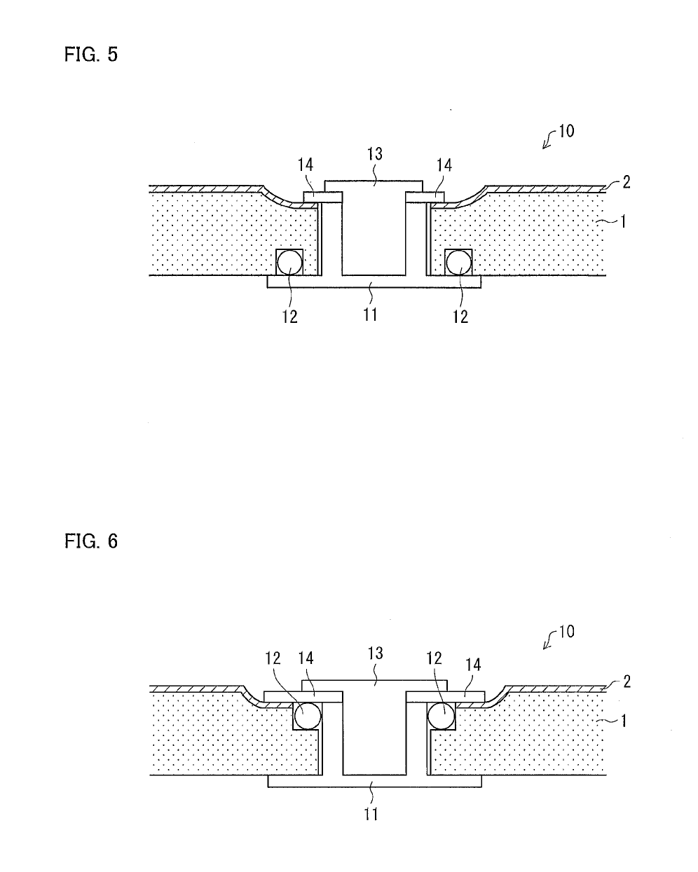

Further, as shown in FIG. 5, the squeeze gasket 12 is not necessarily placed adjacent to the penetrating part 3b (upper part of the electrically conductive pin 11). As long as the squeeze gasket 12 is placed at least between the casing 1 and the electrically conductive member 3, it is possible to improve waterproof and dustproof properties of the structure 10. Furthermore, the arrangement in which the squeeze gasket 12 is placed between the casing 1 and the second part 3c achieves enhancement of the conductive connection between the electrically conductive member 3 and the electrically conductive pattern 2.

However, in the case where the squeeze gasket 12 is placed adjacent to the penetrating part 3b (upper part of the electrically conductive pin 11) as shown in (a) of FIG. 1, it is possible to more suitably obtain the aforementioned effects, such as improvements in waterproof and dustproof properties of the structure 10 and enhancement of the conductive connection between the electrically conductive member 3 and the electrically conductive pattern 2. This is because in a case where which the squeeze gasket 12 is placed so as to be adjacent to the penetrating part 3b, in consideration of warpage of the lower portion of the electrically conductive pin 11 and warpage of the metal plate nut 14, it is possible to more suitably squash the squeeze gasket.

(Wireless Device)

The wireless device 100 includes the structure 10. The wireless device 100 also includes the wireless circuit 30 and the connecting section 20 for connecting between the wireless circuit 30 and the second part 3c of the electrically conductive member 3. This makes it possible to carry out wireless communications by utilizing the electrically conductive pattern 2 as an antenna element.

Apart from the wireless device 100 having the configuration as shown in FIG. 1, the wireless device 100 can include various kinds of components selected according to a use to which the wireless device 100 is put. For example, in a case where the wireless device 100 is constituted as a mobile phone terminal, the wireless device 100 may further include a call receiving section, a call transmitting section, an input section, a display section, a power source section, and others.

(Others)

In addition, a protective layer may be further provided on the outer side of the structure 10 (on the side where the electrically conductive pattern 2 is provided). Provision of the protective layer enables preventing the electrically conductive pattern 2 from suffering damage (disconnection, exfoliation, etc.) and hiding the electrically conductive pattern 2. In the present embodiment, the protective layer may be made of any material (e.g., dielectric resin) that has a strength sufficient to protect the electrically conductive pattern 2 and does not affect the performance of the antenna. Here, the expression that the material does not affect the performance of the antenna means that the presence of the protective layer causes no significant degradation in the performance of the antenna.

The protective layer may be anything as long as it is provided on the electrically conductive pattern 2 by attachment, coating, spraying, or the like method. The protective layer suitably employed can be a layer that is formed by a coating agent (e.g., a resin solution). Further, coating with the coating agent may also serve as painting of the casing 1. Alternatively, the protective layer may be a layer in sheet form that can be attached like a sticker or can be pressed under heat or pressure. Also, it is to be understood a sheet-like protective layer may be one that can be bonded under heat and/or pressure.

### Second Embodiment

Next, the following will discuss another embodiment (Second Embodiment). In the present embodiment, as shown in FIG. 6, the squeeze gasket 12 is placed on the outer side of the casing 1 (i.e., on the upper side of the sheet on which FIG. 6 is illustrated). In other words, the squeeze gasket 12 is placed between the casing 1 and the first part 3a.

The squeeze gasket 12 placed between the casing 1 and the metal plate nut 14 (the first part 3a) is suitably pressed by a force from the electrically conductive member 3 by which the electrically conductive pattern 2 and the surface 1b are sandwiched, thereby successfully sealing a gap between the casing 1 and the metal plate nut 14. This makes it possible to suitably improve waterproof and dustproof properties of the structure.

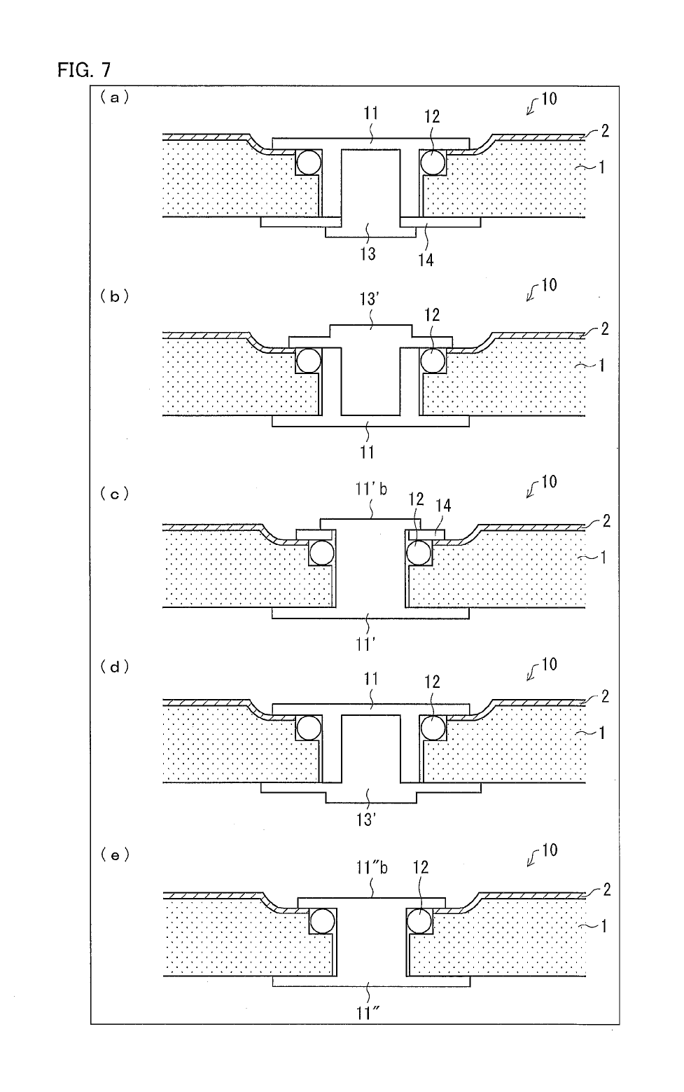

As in First Embodiment, the electrically conductive member 3 can take various forms as shown in FIG. 7. For example, as shown in (a) of FIG. 7, the placements of the electrically conductive pin 11 and the screw 13 may be reversed. In this case, the power-feed contact point for feeding, to the electrically conductive pattern 2, power supplied from the inner side of the casing 1 may be the metal plate nut 14 or the screw 13.

Alternatively, as shown in (b) of FIG. 7, a member 13′, into which the metal plate nut 14 and the screw 13 are integrally formed, may be employed.

Further alternatively, as shown in (c) of FIG. 7, an electrically conductive pin 11′ fixed to the casing 1 by caulking a surface 11′b of the electrically conductive pin 11′ on the outer side of the casing 1, instead of being provided with the screw 13 may be employed.

Alternatively, as shown in (d) of FIG. 7, a member 13′, into which the metal plate nut 14 and the screw 13 both provided in the configuration of (a) of FIG. 7 are integrally formed, may be employed. As shown in (e) of FIG. 7, an electrically conductive pin 11″, into which the metal plate nut 14 and the electrically conductive pin 11′ both provided in the configuration of (c) of FIG. 7 are integrally formed, may be employed.

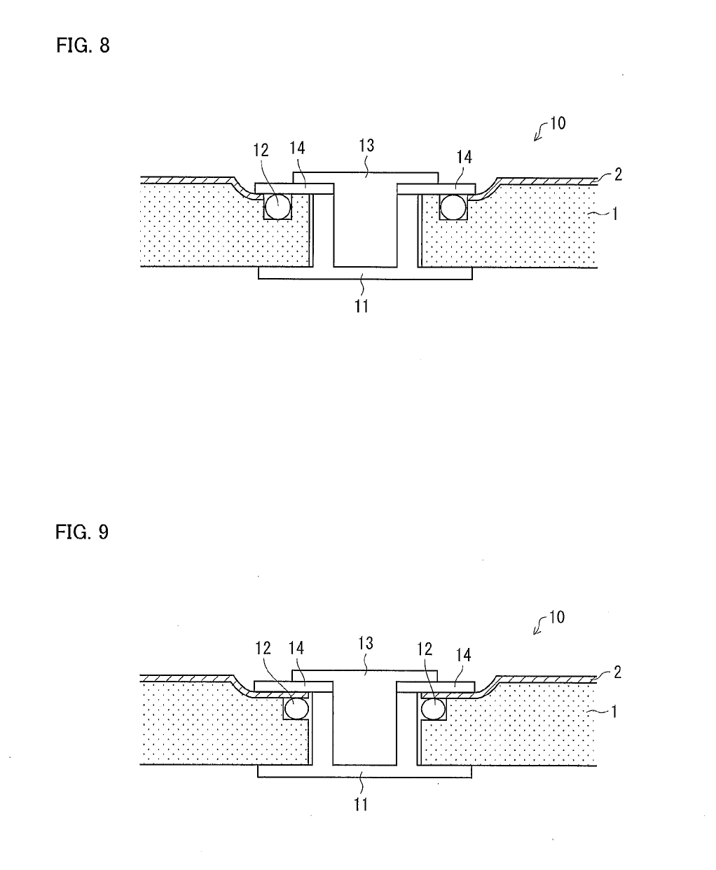

Further, as shown in FIG. 8, the squeeze gasket 12 is not necessarily placed adjacent to the penetrating part 3b.

### Third Embodiment

Next, the following will discuss still another embodiment (Third Embodiment). In the present embodiment, as shown in FIG. 9, the squeeze gasket 12 is placed on the outer side of the casing 1 (i.e., on the upper side of the sheet on which FIG. 9 is illustrated). The squeeze gasket 12 and the metal plate nut 14 (the first part 3a) hold the electrically conductive pattern 2 therebetween.

Note that, in the present embodiment, it is preferable that the electrically conductive pattern 2 be composed of an electrical conductor in sheet form or in plate form. This makes it possible to suitably place the electrically conductive pattern 2 between the squeeze gasket 12 and the metal plate nut 14.

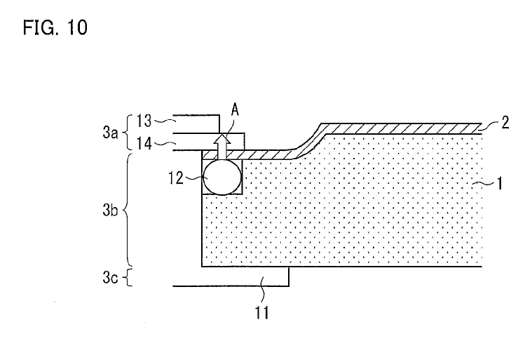

With the arrangement in which the squeeze gasket 12 and the metal plate nut 14 hold the electrically conductive pattern 2 therebetween, the electrically conductive pattern 2 is pressed against the metal plate nut 14 by an elastic force A of the squeeze gasket 12, as shown in FIG. 10. This makes it possible to enhance the conductive connection between the metal plate nut 14 and the electrically conductive pattern 2.

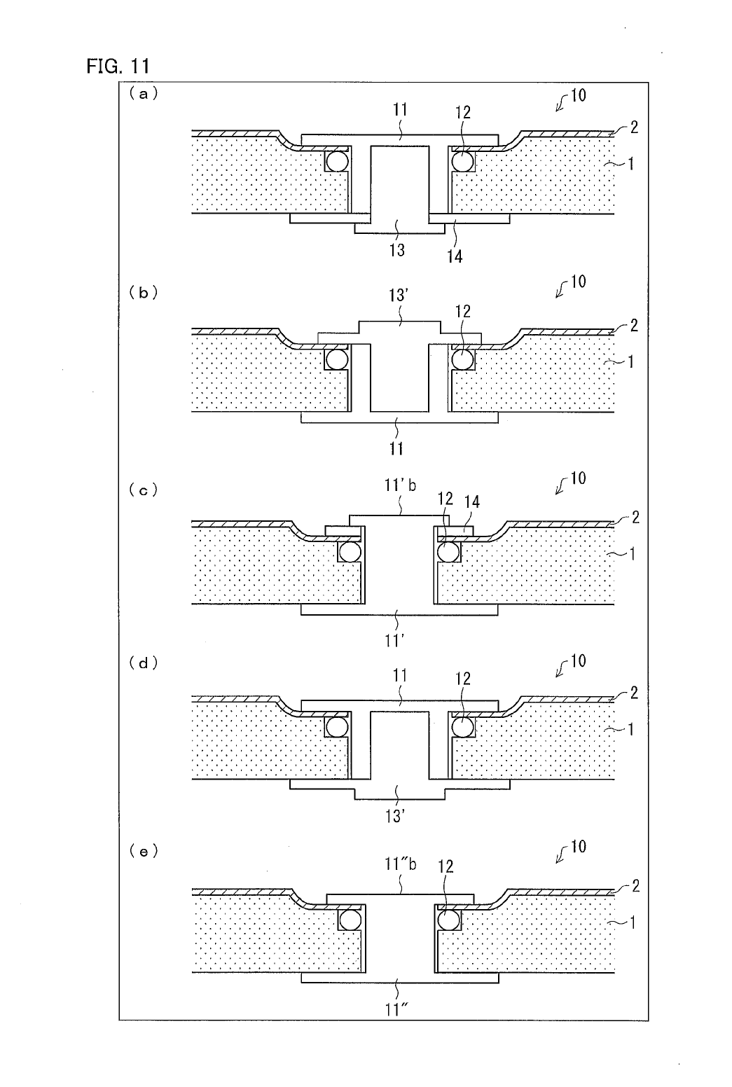

As in First Embodiment, the electrically conductive member 3 can take various forms as shown in FIG. 11. For example, as shown in (a) of FIG. 11, the placements of the electrically conductive pin 11 and the screw 13 may be reversed. In this case, the power-feed contact point for feeding, to the electrically conductive pattern 2, power supplied from the inner side of the casing 1 may be the metal plate nut 14 or the screw 13.

Alternatively, as shown in (b) of FIG. 11, a member 13′, into which the metal plate nut 14 and the screw 13 are integrally formed, may be employed.

Further alternatively, as shown in (c) of FIG. 11, an electrically conductive pin 11′ fixed to the casing 1 by caulking a surface 11′b of the electrically conductive pin 11′ on the outer side of the casing 1, instead of being provided with the screw 13 may be employed.

Alternatively, as shown in (d) of FIG. 11, a member 13′, into which the metal plate nut 14 and the screw 13 both provided in the configuration of (a) of FIG. 11 are integrally formed, may be employed. As shown in (e) of FIG. 11, an electrically conductive pin 11″, into which the metal plate nut 14 and the electrically conductive pin 11′ both provided in the configuration of (c) of FIG. 11 are integrally formed, may be employed.

The present invention is not limited to the aforementioned embodiments and is susceptible of various changes within the scope of the accompanying claims. Also, an embodiment obtained by suitable combinations of technical means disclosed in the different embodiments is included within the technical scope of the present invention.

(Outline)

That is, a structure according to the present invention includes: a casing being made of a dielectric material; an electrically conductive pattern being provided on a first surface of the casing; an electrically conductive member including: a penetrating part penetrating the casing so as to extend from the first surface to a second surface opposite the first surface; a first part extending from the penetrating part toward the first surface; and a second part extending from the penetrating part toward the second surface, wherein the first part and the second part catch the electrically conductive pattern and the second surface therebetween; and a squeeze gasket being composed of an elastic body and placed between the casing and the electrically conductive member.

According to the above arrangement, the electrically conductive member penetrates the casing and holds the casing and the electrically conductive pattern from both sides thereof between the first part and the second part thereof. This causes the electrically conductive member to be fastened to the casing. Further, the first part comes into contact with the electrically conductive pattern. This enables electrical connection between the electrically conductive member and the electrically conductive pattern, thus allowing power supplied from the second surface side of the casing to be fed to the electrically conductive pattern.

In the above arrangement, the squeeze gasket composed of an elastic body is placed between the electrically conductive member and the casing. This makes it possible to seal a gap between the electrically conductive member and the casing, thus achieving improvements in waterproof and dustproof properties of the structure.

The structure according to the present invention is preferably such that the squeeze gasket is placed between the casing and the second part.

According to the above arrangement, the squeeze gasket placed between the casing and the second part applies, by its elastic force, a force directing from the first surface to the second surface, to the second part of the electrically conductive member. This force is transmitted to the first part. This increases a force applied by the first part to catch the electrically conductive pattern. As such, it is possible to enhance the conductive connection between the first part and the electrically conductive pattern.

Further, the structure according to the present invention may be such that the squeeze gasket is placed between the casing and the first part.

According to the above arrangement, the squeeze gasket placed between the casing and the first part is suitably pressed by a force from the electrically conductive member by which the electrically conductive pattern and the second surface are sandwiched, thereby successfully sealing a gap between the casing and the first part. This makes it possible to suitably improve waterproof and dustproof properties of the structure.

The structure according to the present invention may be such that the electrically conductive pattern is composed of an electrical conductor in sheet form or in plate form, and the squeeze gasket and the first part hold the electrically conductive pattern therebetween.

According to the above arrangement, the electrically conductive pattern is composed of an electrical conductor in sheet form or in plate form. It is therefore possible to place the electrically conductive pattern between the squeeze gasket and the first part. In addition, the squeeze gasket presses, by its elastic force, the electrically conductive pattern against the first part. This makes it possible to enhance the conductive connection between the first part and the electrically conductive pattern.

The structure according to the present invention may be such that the electrically conductive pattern is composed of an electrical conductor in sheet form or in plate form, and the squeeze gasket is placed between the casing and the second part.

According to the above arrangement, even in a case where the electrically conductive pattern is composed of an electrical conductor in sheet form or in plate form, the squeeze gasket is placed between the casing and the second part. This causes the squeeze gasket to apply, by its elastic force, a force directing from the first surface to the second surface, to the electrically conductive member. This increases a force applied by the first part to catch the electrically conductive pattern. As such, it is possible to enhance the conductive connection between the first part and the electrically conductive pattern.

The structure according to the present invention is preferably such that the squeeze gasket is placed at a position in contact with the penetrating part.

Both the first part and the second part between which the electrically conductive pattern and the second surface are caught extend from the penetrating part. According to the above arrangement, it is possible to suitably squash the squeeze gasket. This is because a force applied by the first part and the second part to sandwich the electrically conductive pattern and the second surface therebetween becomes larger in an area adjacent to the penetrating part, which area is less susceptible to warpage or the like of the first part and the second part. As such, it is possible to more suitably obtain the aforementioned effects, such as improvements in waterproof and dustproof properties of the structure.

### INDUSTRIAL APPLICABILITY

The present invention is applicable in the field of manufacture of an electronic device, typified by a wireless device, having an electrically conductive pattern provided therein.

### REFERENCE SIGNS LIST

1 Casing
2 Electrically conductive pattern
3 Electrically conductive member
3a First part
3b Penetrating part
3c Second part
10 Structure
11 Electrically conductive pin
12 Squeeze gasket
13 Screw
14 Metal plate nut
20 Connecting section
30 Wireless circuit
100 Wireless device

1-6. (canceled)

7. A structure comprising:
a casing being made of a dielectric material;
an electrically conductive pattern being provided on a first surface of the casing;
an electrically conductive member including: a penetrating part penetrating the casing so as to extend from the first surface to a second surface opposite the first surface; a first part extending from the penetrating part toward the first surface; and a second part extending from the penetrating part toward the second surface, wherein the first part and the second part hold the electrically conductive pattern and the second surface therebetween; and
a squeeze gasket being composed of an elastic body and placed between the casing and the second part,
the first surface being a surface on an outer side of the casing, while the second surface being a surface on an inner side of the casing.

8. A structure comprising:
a casing being made of a dielectric material;
an electrically conductive pattern being provided on a first surface of the casing;
an electrically conductive member including: a penetrating part penetrating the casing so as to extend from the first surface to a second surface opposite the first surface; a first part extending from the penetrating part toward the first surface; and a second part extending from the penetrating part toward the second surface, wherein the first part and the second part hold the electrically conductive pattern and the second surface therebetween; and
a squeeze gasket being composed of an elastic body and placed between the casing and the first part,
the electrically conductive pattern being composed of an electrical conductor in sheet form or in plate form,
the squeeze gasket and the first part, holding the electrically conductive pattern therebetween.

9. The structure according to claim 7, wherein
the electrically conductive pattern is composed of an electrical conductor in sheet form or in plate form.

10. The structure according to claim 7, wherein
the squeeze gasket is placed at a position in contact with the penetrating part.

11. A structure comprising:
a casing being made of a dielectric material;
an electrically conductive pattern being provided on a first surface of the casing;
an electrically conductive member including: a penetrating part penetrating the casing so as to extend from the first surface to a second surface opposite the first surface; a first part extending from the penetrating part toward the first surface; and a second part extending from the penetrating part toward the second surface, wherein the first part and the second part hold the electrically conductive pattern and the second surface therebetween; and
a squeeze gasket being composed of an elastic body and placed between the casing and the electrically conductive member,
the electrically conductive pattern being an antenna element,
the second part of the electrically conductive member, being a power-feed contact point for feeding, to the antenna element, power supplied from a side of the second surface.

12. The structure according to claim 8, wherein
the squeeze gasket is placed at a position in contact with the penetrating part.

13. The structure according to claim 9, wherein
the squeeze gasket is placed at a position in contact with the penetrating part.
